(19) United States
(12) Patent Application Publication
(10) Pub. No.: US 2026/0367281 A1
(43) Pub. Date: Nov. 19, 2026

(54) PHOTONIC CHIP STRUCTURE AND SEMICONDUCTOR PACKAGE COMPRISING SAME

(71) Applicant: SAMSUNG ELECTRONICS CO., LTD., Suwon-si (KR)

(72) Inventor: Jung Hua CHANG, Suwon-si (KR)

(73) Assignee: SAMSUNG ELECTRONICS CO., LTD., Suwon-si (KR)

(21) Appl. No.: 19/668,942

(22) Filed: May 6, 2026

(30) Foreign Application Priority Data
May 16, 2025 (KR) 10-2025-0064209

(51) Int. Cl. G02B 1/00; H10W 42/00; H10W 74/10; H10W 90/10

(52) U.S. Cl. CPC G02B 1/00; H10W 42/121; H10W 74/111; H10W 90/10

(57) ABSTRACT

A photonic chip structure including a photonic integrated circuit chip, a protective layer disposed over the photonic integrated circuit chip, a metalens disposed between the photonic integrated circuit chip and the protective layer, and having an upper surface configured to directly contact a lower surface of the protective layer, and an optical coupler located inside the photonic integrated circuit chip and disposed to vertically overlap the metalens.

### CROSS-REFERENCE TO RELATED APPLICATION

This application is based on and claims priority under 35 U.S.C. §119 to Korean Patent Application No. 10-2025-0064209, filed on May 16, 2025, in the Korean Intellectual Property Office, the disclosure of which is incorporated by reference herein in its entirety.

### BACKGROUND

The inventive concept relates to a photonic chip structure and a semiconductor package including the same, and more particularly, to a photonic chip structure including a two-dimensional planar lens of which an upper surface is protected by a protection layer, and to a semiconductor package including the same.

With rapid advancements in the electronics industry and growing user demands, electronic devices have become increasingly miniaturized and lightweight. As electronic devices are miniaturized and lightweight, semiconductor packages used therein are also being miniaturized and reduced in weight, and higher integration of semiconductor devices is being required. Accordingly, semiconductor packages containing multiple semiconductor chips are being developed to provide multifunctionality.

With an advancement in photonic integrated circuit (PIC) technology, techniques for integrating optical elements on semiconductor chips, which perform a function of converting optical signals into electrical signals and vice versa, are being actively developed. Such optical elements play a key role in various applications including high-speed communication, optical sensors, LiDAR, and quantum information processing, and accordingly, packaging technologies for integration and protection of optical elements are gaining importance.

### SUMMARY

The inventive concept provides a photonic chip structure with improved reliability and a semiconductor package including the same.

In addition, the inventive concept is not limited to the issues mentioned above, and other issues may be clearly understood by those skilled in the art from the description below.

According to an aspect of the inventive concept, there is provided a photonic chip structure including a photonic integrated circuit chip, a protective layer disposed over the photonic integrated circuit chip, a metalens disposed between the photonic integrated circuit chip and the protective layer, and having an upper surface configured to directly contact a lower surface of the protective layer, and an optical coupler located inside the photonic integrated circuit chip and disposed to vertically overlap the metalens.

In addition, according to another aspect of the inventive concept, there is provided a photonic chip structure including a photonic integrated circuit chip, an optical coupler located inside the photonic integrated circuit chip, a protective layer disposed over the photonic integrated circuit chip, and a metalens, to transmit optical signals transmitted through the protective layer to the optical coupler, disposed between the photonic integrated circuit chip and the protective layer and vertically aligned with the optical coupler and the protective layer.

Furthermore, according to another aspect of the inventive concept, there is provided a semiconductor package including a package substrate, a semiconductor chip structure arranged over the package substrate, a photonic chip structure arranged to be horizontally spaced apart from the semiconductor chip structure on the package substrate, and a package molding layer surrounding the semiconductor chip structure and the photonic chip structure on the package substrate, wherein the photonic chip structure includes a photonic integrated circuit chip, a protective layer disposed over the photonic integrated circuit chip, a metalens disposed between the photonic integrated circuit chip and the protective layer, and having an upper surface configured to directly contact a lower surface of the protective layer, and an optical coupler located inside the photonic integrated circuit chip and disposed to vertically overlap the metalens.

### BRIEF DESCRIPTION OF THE DRAWINGS

Embodiments will be more clearly understood from the following detailed description taken in conjunction with the accompanying drawings in which:

FIG. 1 is a plan view schematically illustrating a semiconductor package according to an embodiment;

FIG. 2 is a cross-sectional view schematically illustrating the semiconductor package of FIG. 1 taken along line I–I′;

FIG. 3 is a cross-sectional view schematically illustrating the semiconductor package of FIG. 1 taken along line II–II′;

FIG. 4 is a cross-sectional view schematically illustrating a photonic chip structure according to an embodiment;

FIG. 5 is a plan view schematically illustrating a metalens according to an embodiment;

FIG. 6 is a cross-sectional view schematically illustrating a photonic chip structure according to an embodiment;

FIG. 7 is a cross-sectional view schematically illustrating a photonic chip structure according to an embodiment;

FIG. 8 is a cross-sectional view schematically illustrating a semiconductor package according to an embodiment;

FIG. 9 is a cross-sectional view schematically illustrating a photonic chip structure according to an embodiment;

FIGS. 10, 11, 12, 13, 14, 15, 16, 17, 18, 19, 20, 21, 22, 23, and 24 are views schematically illustrating a process of fabricating the semiconductor package of FIGS. 1, 2, 3, and 4; and

FIGS. 25, 26, 27, 28, 29, and 30 are views schematically illustrating a process of fabricating the photonic chip structure of FIG. 6.

### DETAILED DESCRIPTION OF THE EMBODIMENTS

Hereinafter, embodiments will be described in detail with reference to the accompanying drawings. The same reference numerals are used for the same components in the drawings, and repeated descriptions thereof will be omitted.

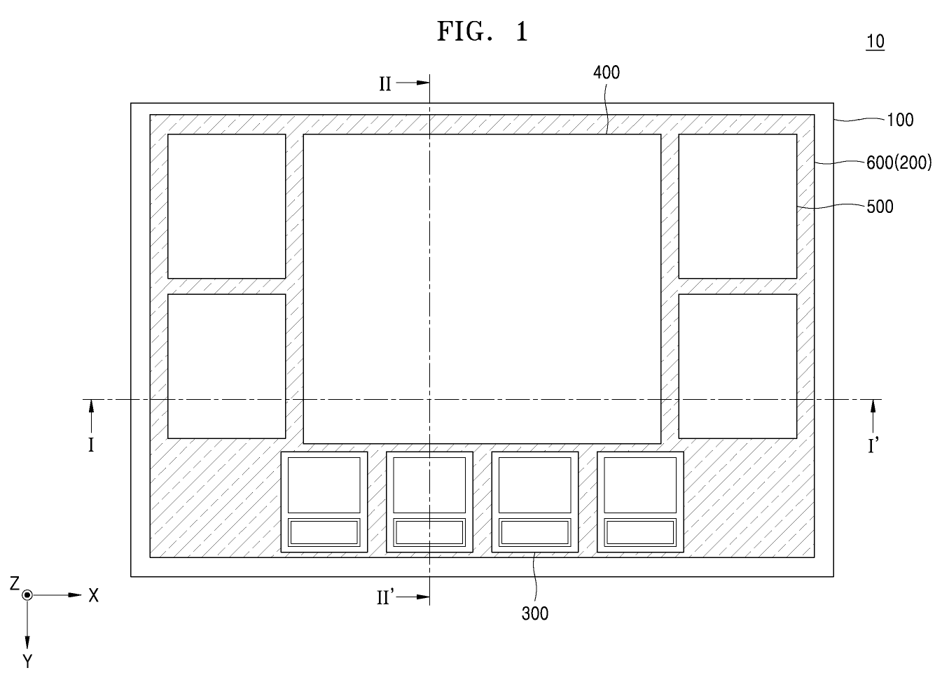

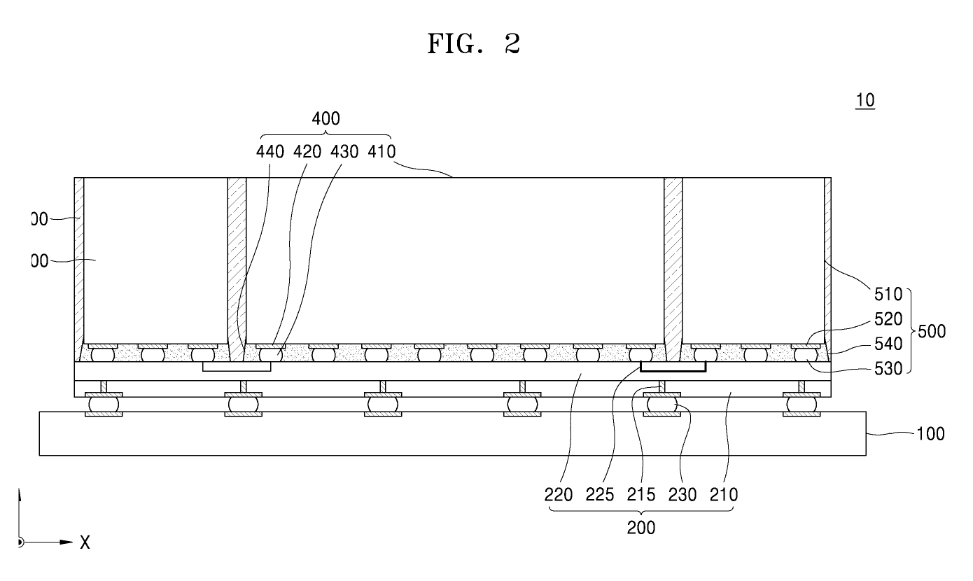

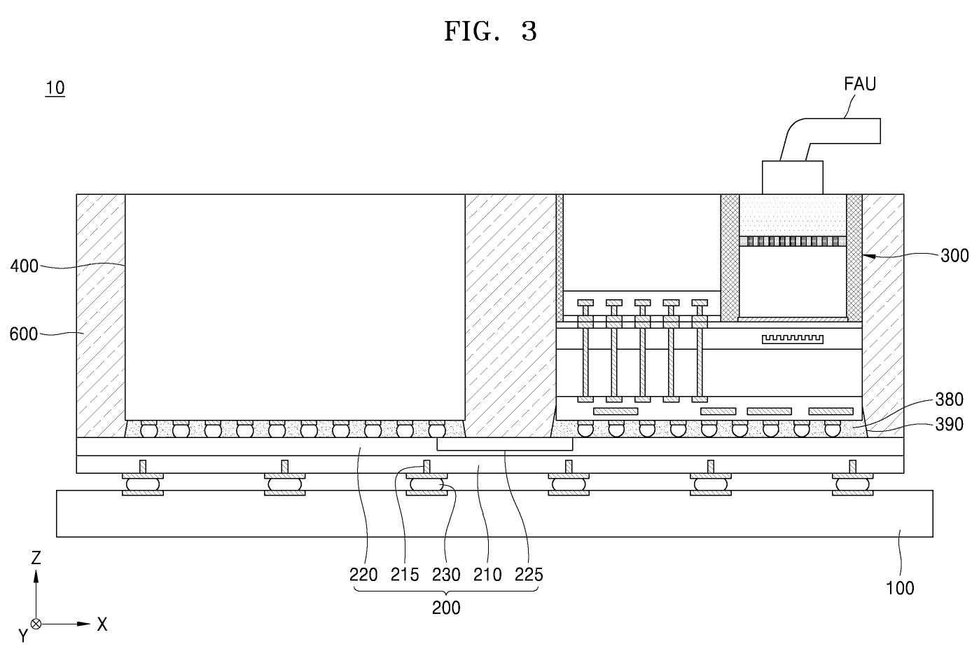

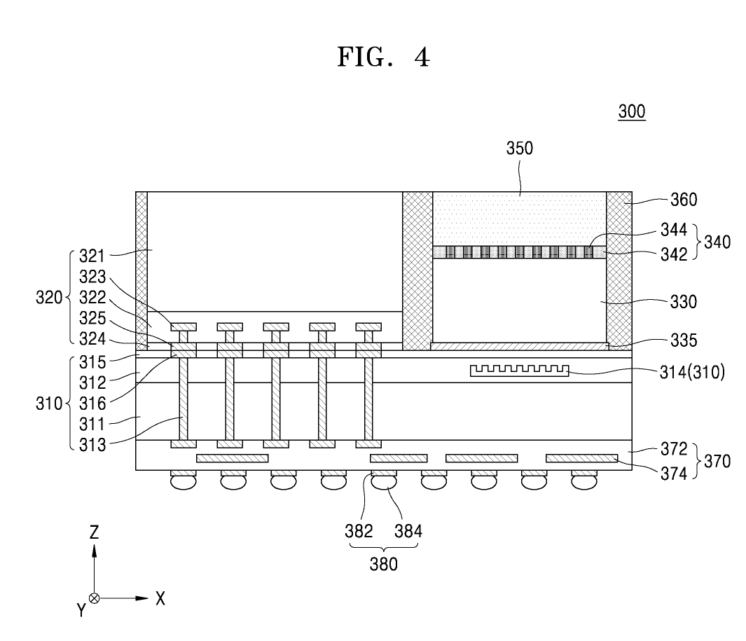

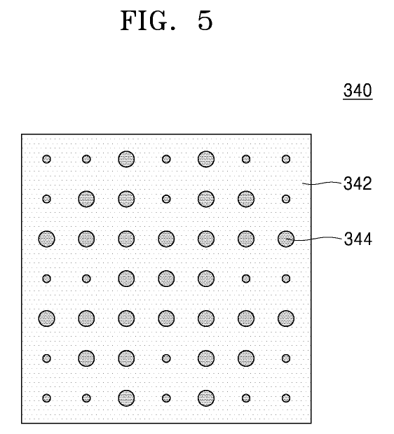

FIG. 1 is a plan view schematically illustrating a semiconductor package 10 according to an embodiment. FIG. 2 is a cross-sectional view schematically illustrating the semiconductor package 10 of FIG. 1 taken along line I–I′. FIG. 3 is a cross-sectional view schematically illustrating the semiconductor package 10 of FIG. 1 taken along line II–II′. FIG. 4 is a cross-sectional view schematically illustrating a photonic chip structure 300 according to an embodiment. FIG. 5 is a plan view schematically illustrating a metalens 340 according to an embodiment.

Referring to FIGS. 1 - 4, the semiconductor package 10 may include a first package substrate 100, a second package substrate 200, a photonic chip structure 300, a first chip structure 400, a second chip structure 500, and a package molding layer 600. According to some embodiments, the semiconductor package 10 may be a semiconductor package that communicates with an external device through optical signals. The semiconductor package 10 may be a semiconductor package including an optical engine. At least one of the first chip structure 400 and the second chip structure 500 may correspond to a semiconductor chip structure.

Hereinafter, unless otherwise defined, a direction parallel to an upper surface of the first package substrate 100 is defined as a first horizontal direction (X direction), a direction perpendicular to the upper surface of the first package substrate 100 is defined as a vertical direction (Z direction), and a direction perpendicular to both the first horizontal direction (X direction) and the vertical direction (Z direction) is defined as a second horizontal direction (Y direction).

First, the photonic chip structure 300 may be an optical engine that receives optical signals from an external device and converts the optical signals into electrical signals, or transmits internal electrical signals to the outside as optical signals. The photonic chip structure 300 may be mounted over the second package substrate 200 and may be electrically connected to the first chip structure 400 or the second chip structure 500 through the second package substrate 200.

The photonic chip structure 300 may include a photonic integrated circuit chip 310, an electronic integrated circuit chip 320, an optical block 330, a metalens 340, a protective layer 350, a molding layer 360, a redistribution structure 370, and connection terminals 380.

According to some embodiments, the photonic integrated circuit chip 310 may include a first substrate 311, a first interlayer insulating layer 312, through electrodes 313, an optical coupler 314, a first passivation layer 315, and a first connection pad 316.

The photonic integrated circuit chip 310 may include an active surface and an inactive surface opposite to the active surface. In some embodiments, the photonic integrated circuit chip 310 may be arranged such that the active surface of the photonic integrated circuit chip 310 faces upward.

The first substrate 311 may include a semiconductor material such as silicon or germanium. The first substrate 311 may include an upper surface and a lower surface opposite to the upper surface. Here, the lower surface of the first substrate 311 may face the redistribution structure 370. For example, the upper surface of the first substrate 311 may be the active surface, and the lower surface of the first substrate 311 may be the inactive surface. The through electrode 313 may penetrate the first substrate 311 and extend from the upper surface to the lower surface of the first substrate 311. In this case, a lower end of the through electrode 313 may be in contact with a connection pad and may be electrically connected to the redistribution structure 370.

The first interlayer insulating layer 312 may be disposed on the upper surface of the first substrate 311. For example, the first interlayer insulating layer 312 may have a constant thickness and be formed along the upper surface of the first substrate 311. According to some embodiments, the first interlayer insulating layer 312 may include an inorganic insulating layer such as silicon oxide (SiO) or silicon nitride (SiN). Alternatively, the first interlayer insulating layer 312 may include a polymer material. Alternatively, the first interlayer insulating layer 312 may include an insulating polymer or a photoimageable dielectric (PID). For example, the photoimageable dielectric may include at least one of a photosensitive polyimide, a polybenzoxazole (PBO), a phenol-based polymer, or a benzocyclobutene-based polymer. The first interlayer insulating layer 312 may be formed of two or more insulating materials stacked on one another.

The through electrode 313 may be formed by penetrating the first substrate 311 and the first interlayer insulating layer 312. Specifically, the through electrode 313 may extend from the lower surface of the first substrate 311 to the first connection pad 316.

The through electrode 313 may include a conductive material that may include, for example, copper (Cu), gold (Au), silver (Ag), nickel (Ni), tungsten (W), aluminum (Al), or a combination thereof. In some embodiments, the through electrode 313 may further include a barrier material for preventing the conductive material from diffusing out of the through electrode 313. The barrier material may include, for example, titanium (Ti), tantalum (Ta), titanium nitride (TiN), tantalum nitride (TaN), or a combination thereof.

In FIG. 4, the through electrode 313 is illustrated as being connected to the first connection pad 316 through the first interlayer insulating layer 312, but the inventive concept is not limited thereto, and the through electrode 313 may be connected to the first interlayer insulating layer 312 by penetrating only the first substrate 311. In this case, the first interlayer insulating layer 312 may further include a wiring pattern therein. For example, the wiring pattern may include wiring lines extending in the horizontal direction (X direction and/or Y direction), and wiring vias connecting the wiring lines vertically, thereby electrically connecting the through electrode 313 and the first connection pad 316.

The optical coupler 314 may be located inside the photonic integrated circuit chip 310. For example, the optical coupler 314 may be embedded in the first interlayer insulating layer 312. The optical coupler 314 may be configured to couple optical signals incident to the optical block 330 through a fiber array unit (FAU). Specifically, the optical signals that reach the optical coupler 314 through the optical block 330 may be coupled to another waveguide. Although not illustrated, a waveguide and an optical component may be located in the first interlayer insulating layer 312, and the optical coupler 314 may be located in a region of the waveguide. The waveguide may be formed of a patterned silicon layer and may extend along the first horizontal direction (X direction). In some embodiments, the waveguide may be a silicon waveguide including silicon, and the first interlayer insulating layer 312 may be a buried oxide (BOX) layer. However, the inventive concept is not limited thereto, and the waveguide may be covered by an oxide layer that is distinct from the first interlayer insulating layer 312. The optical component may be connected to the waveguide and may convert optical signals into electrical signals or convert electrical signals into optical signals. The optical component may include a photodetector, a photodiode, or a modulator.

The optical coupler 314 may be disposed to be aligned with the optical block 330. For example, the optical coupler 314 may be disposed in the first interlayer insulating layer 312 so as to vertically overlap the optical block 330. Although FIG. 4 illustrates one optical coupler 314, a plurality of optical couplers may be provided depending on an arrangement of the fiber array unit FAU over an upper portion of the optical block 330.

The optical coupler 314 may be disposed to vertically overlap the metalens 340. For example, the optical coupler 314 may receive optical signals from the metalens 340, or the optical signals transmitted from the optical coupler 314 may be delivered to the fiber array unit FAU through the metalens 340.

In FIG. 4, the optical coupler 314 is illustrated as having a grating coupler shape, but the type of the optical coupler 314 is not limited thereto. The optical coupler 314 may include at least one of a grating coupler, an edge coupler, and an evanescent coupler. According to some embodiments, when the optical coupler 314 is the edge coupler or the evanescent coupler, the photonic integrated circuit chip 310 may further include a reflective structure for delivering optical signals, which exit from the fiber array unit FAU and sequentially pass through the protective layer 350 and the metalens 340, to the optical coupler 314.

The first passivation layer 315 may be disposed on the first interlayer insulating layer 312. The first passivation layer 315 may serve to protect the first interlayer insulating layer 312 and the underlying structure. The first passivation layer 315 may be formed of an insulating material, and may include, for example, SiCN.

The first connection pad 316 may be disposed on the first interlayer insulating layer 312. For example, the first connection pad 316 may be embedded in the first passivation layer 315, and side surfaces of the first connection pad 316 may be surrounded by the first passivation layer 315. In addition, the upper surface of the first connection pad 316 may not be covered by the first passivation layer 315. The upper surface of the first connection pad 316 may be located on the same vertical level as an upper surface of the first passivation layer 315. The first connection pad 316 may be electrically connected to the through electrode 313 and may be coupled to a second connection pad 325 of the electronic integrated circuit chip 320.

According to some embodiments, the electronic integrated circuit chip 320 may be mounted on the photonic integrated circuit chip 310. For example, the electronic integrated circuit chip 320 may be disposed on the active surface of the photonic integrated circuit chip 310. The electronic integrated circuit chip 320 may be disposed on the photonic integrated circuit chip 310 to be spaced apart from the optical block 330 in the horizontal direction (X direction and/or Y direction). The electronic integrated circuit chip 320 may be configured to interconnect the photonic integrated circuit chip 310 and chip structures (e.g., the first chip structure 400 and the second chip structure 500). For example, in converting electrical signals, the electronic integrated circuit chip 320 may convert the electrical signals so as to be matched with the chip structures (e.g., the first chip structure 400 and the second chip structure 500).

In some embodiments, a horizontal width of the electronic integrated circuit chip 320 may be smaller than a width of the photonic integrated circuit chip 310. A footprint of the electronic integrated circuit chip 320 may be smaller than a footprint of the photonic integrated circuit chip 310.

The electronic integrated circuit chip 320 may include a second substrate 321, a second interlayer insulating layer 322, a wiring structure 323, a second passivation layer 324, and a second connection pad 325.

The second substrate 321 may include a semiconductor material such as silicon or germanium. The second substrate 321 may include an active surface and an inactive surface opposite to the active surface. In some embodiments, the electronic integrated circuit chip 320 may include a plurality of individual elements used for interfacing with the photonic integrated circuit chip 310. The plurality of individual elements of the electronic integrated circuit chip 320 may be disposed on the active surface of the second substrate 321. Here, the active surface of the second substrate 321 may be a lower surface of the second substrate 321. For example, the electronic integrated circuit chip 320 may include complementary metal-oxide-semiconductor (CMOS) drivers, transimpedance amplifiers, and the like to perform functions such as controlling high-frequency signaling of the photonic integrated circuit chip 310.

According to an embodiment, the second interlayer insulating layer 322 may be disposed on an upper surface of the second substrate 321. For example, the second interlayer insulating layer 322 may be formed along the upper surface of the second substrate 321 with a constant thickness. According to some embodiments, the second interlayer insulating layer 322 may include an inorganic insulating layer such as silicon oxide (SiO) or silicon nitride (SiN). Alternatively, the second interlayer insulating layer 322 may include a polymer material. Alternatively, the second interlayer insulating layer 322 may include an insulating polymer or a PID. For example, the photoimageable dielectric may include at least one of the photosensitive polyimide, the PBO, the phenol-based polymer, or the benzocyclobutene-based polymer. The second interlayer insulating layer 322 may be composed of two or more insulating materials laminated with each other.

The wiring structure 323 may be located in the second interlayer insulating layer 322. The wiring structure 323 may be connected to individual elements located on the active surface of the second substrate 321. In addition, the wiring structure 323 may be electrically connected to the second connection pad 325. According to an embodiment, the wiring structure 323 may include wiring lines extending in the horizontal direction (X direction and/or Y direction) and wiring vias connecting wiring lines vertically, thereby electrically connecting the individual elements and the second connection pad 325.

A second passivation layer 324 may be disposed on the second interlayer insulating layer 322. The second passivation layer 324 may serve to protect the second interlayer insulating layer 322 and the wiring structure 323. The second passivation layer 324 may be formed of an insulating material and may include, for example, SiCN.

The second connection pad 325 may be disposed on the second interlayer insulating layer 322. For example, the second connection pad 325 may be embedded in the second passivation layer 324, and side surfaces of the second connection pad 325 may be surrounded by the second passivation layer 324. In addition, a lower surface of the second connection pad 325 may not be covered by the second passivation layer 324. The lower surface of the second connection pad 325 may be located at a same vertical level as the lower surface of the second passivation layer 324. The second connection pad 325 may be electrically connected to the wiring structure 323 and may be coupled to the first connection pad 316 of the photonic integrated circuit chip 310.

In some embodiments, the electronic integrated circuit chip 320 and the photonic integrated circuit chip 310 may be coupled by direct bonding. The direct bonding may include dielectric-to-dielectric bonding, copper-to-copper bonding, and hybrid bonding by which both dielectric-to-dielectric bonding and metal-to-metal bonding occur. In this case, the first connection pad 316 and the second connection pad 325 may be coupled by diffusion bonding caused by heat. However, the electronic integrated circuit chip 320 and the photonic integrated circuit chip 310 may also be electrically connected by connection terminals such as solder balls or by adhesive films such as anisotropic conductive films (ACF) or non-conductive films (NCF).

FIG. 4 illustrates that the electronic integrated circuit chip 320 is disposed on the photonic integrated circuit chip 310 to be spaced apart from the optical block 330 in the horizontal direction (X direction and/or Y direction), but this is not limited thereto. The electronic integrated circuit chip 320 may be disposed at various positions so as to be electrically connected to the photonic integrated circuit chip 310. For example, the electronic integrated circuit chip 320 may be arranged side by side with the photonic integrated circuit chip 310 in the horizontal direction (X direction and/or Y direction) over the second package substrate 200, or may be disposed on a lower portion of the photonic integrated circuit chip 310.

The optical block 330 may be disposed over the photonic integrated circuit chip 310. For example, the optical block 330 may be disposed over the photonic integrated circuit chip 310 to be spaced apart from the electronic integrated circuit chip 320 in the first horizontal direction (X direction). The optical block 330 may be disposed above the optical coupler 314 of the photonic integrated circuit chip 310. A horizontal width of the optical block 330 may be smaller than that of the photonic integrated circuit chip 310.

The optical block 330 may have a constant refractive index. For example, the optical block 330 may be formed to include silicon, glass, or polymer. An optical path for delivering external optical signals to the photonic integrated circuit chip 310 may be provided (formed?) in the optical block 330.

An optical adhesive layer 335 may be provided on a lower surface of the optical block 330. The optical block 330 may be attached to the photonic integrated circuit chip 310 with the optical adhesive layer 335 therebetween. The optical adhesive layer 335 may attach the optical block 330 on the photonic integrated circuit chip 310 such that optical signals passing through the optical block 330 are deliverable to the optical coupler 314. In some embodiments, the optical adhesive layer 335 may include an optically clear adhesive (OCA) or an optical glue. For example, the optical adhesive layer 335 may be formed to include an acrylic resin, a silicone resin, a polyurethane resin, or an epoxy resin.

In some embodiments, the optical adhesive layer 335 may be omitted. In this case, the optical block 330 may be coupled on the photonic integrated circuit chip 310 by using oxide bonding or hybrid bonding.

The metalens 340 may be disposed to be vertically aligned with the protective layer 350 and the optical coupler 314 of the photonic integrated circuit chip 310. In some embodiments, the metalens 340 may be disposed on an upper surface of the optical block 330. For example, the metalens 340 may be integrally formed on the upper surface of the optical block 330.

The metalens 340 may be formed as a thin planar lens in which nano-structures smaller than a wavelength of light are arranged on a planar surface. In some embodiments, the metalens 340 may be formed to have a thickness of 5 μm or less in the vertical direction (Z direction). In some embodiments, the metalens 340 may include two or more inorganic materials having different refractive indices.

Referring to FIGS. 4 and 5, the metalens 340 may include a planar portion 342 and a plurality of nano-structures 344.

The planar portion 342 may have a first refractive index n1 in a two-dimensional planar structure. The planar portion 342 may be configured such that optical signals delivered to the metalens 340 pass efficiently through the nano-structures 344. The planar portion 342 may include a material having a relatively low refractive index. For example, the planar portion 342 may include SiO₂.

The plurality of nano-structures 344 may have a second refractive index n2 and may be arranged spaced apart from each other within the planar portion 342. The plurality of nano-structures 344 may each have a shape such as a nanopillar, pin, or disk. In some embodiments, each of the plurality of nano-structures 344 may extend from the upper surface to the lower surface of the planar portion 342. For example, each of the plurality of nano-structures 344 may be formed to penetrate the planar portion 342 and may have a same thickness as the planar portion 342.

Each of the plurality of nano-structures 344 may be formed to have a size smaller than a wavelength of light. The plurality of nano-structures 344 may be configured to change phases and focal points of optical signals delivered to the metalens 340. For example, the plurality of nano-structures 344 may impart a phase delay to light passing through them. Accordingly, the focal points of the optical signals passing through the metalens 340 may be adjusted. The plurality of nano-structures 344 may include a material having a relatively high refractive index. For example, the plurality of nano-structures 344 may include TiO₂ or Si. In some embodiments, the second refractive index n2 of the plurality of nano-structures 344 may refer to an effective refractive index determined based on at least one of a material, a size, a shape, a height, a pitch, an arrangement, and a filling ratio of the plurality of nano-structures 344. For example, the second refractive index n2 may be determined by collective optical characteristics of the plurality of nano-structures 344, rather than only by a refractive index of a material included in each of the plurality of nano-structures 344.

Depending on embodiments, the plurality of nano-structures 344 having different sizes may be arranged on the planar portion 342. Although FIG. 5 illustrates nano-structures 344 of two different sizes, sizes and patterns of the nano-structures 344 are not limited thereto. The metalens 340 may include two or more nano-structures 344 of different sizes, and the nano-structures 344 may be appropriately arranged according to a target light path and focal point.

The first refractive index n1 of the planar portion 342 and the second refractive index n2 of the plurality of nano-structures 344 may have different values. The second refractive index n2 may have a value greater than the first refractive index n1. In some embodiments, a ratio of the first refractive index n1 to the second refractive index n2 may be greater than 1.2 and less than 5. That is, the planar portion 342 and the plurality of nano-structures 344 may respectively have the first refractive index n1 and the second refractive index n2 such that 1.2 < n2/n1 < 5 is satisfied.

The protective layer 350 may be disposed over an upper surface of the metalens 340. The protective layer 350 may be disposed to cover the entire upper surface of the metalens 340 so as to protect the metalens 340. A lower surface of the protective layer 350 may be directly disposed on the upper surface of the metalens 340. For example, the protective layer 350 may be coupled to the upper surface of the metalens 340 by oxide bonding. However, such coupling is not limited thereto, and the protective layer 350 may also be coupled to the metalens 340 by using optical glue.

The metalens 340 and the protective layer 350 may be sequentially stacked over the upper portion of the photonic integrated circuit chip 310. For example, the metalens 340 may be disposed on the upper surface of the optical block 330, and the protective layer 350 may be disposed on the upper surface of the metalens 340. The protective layer 350 may be disposed to vertically overlap the metalens 340, the optical block 330, and the optical coupler 314. The fiber array unit FAU may be disposed over an upper surface of the protective layer 350, and the protective layer 350 may serve as an optical path for delivering optical signals transmitted from the fiber array unit FAU to the metalens 340.

The protective layer 350 may have a light transmittance in excess of 85% for light of a wavelength of 1200 nm to 1700 nm. For example, the protective layer 350 may include Si, glass, polymer, or the like.

The molding layer 360 may seal the electronic integrated circuit chip 320, the optical block 330, the metalens 340, and the protective layer 350 on the photonic integrated circuit chip 310. The molding layer 360 may cover the upper surface of the first passivation layer 315 of the photonic integrated circuit chip 310 and may surround a side surface of the electronic integrated circuit chip 320, a side surface of the optical block 330, a side surface of the metalens 340, and a side surface of the protective layer 350. The molding layer 360 may be formed not to cover the upper surface of the electronic integrated circuit chip 320 and the upper surface of the protective layer 350. For example, an upper surface of the molding layer 360 may be located on a same vertical level as the upper surface of the electronic integrated circuit chip 320 and the upper surface of the protective layer 350.

The molding layer 360 may include, for example, a thermosetting resin such as epoxy resin, a thermoplastic resin such as polyimide, or a resin including an inorganic filler therein, and specifically may include Ajinomoto Build-up Film (ABF), Flame Retardant Type 4 (FR-4), Bismaleimide-Triazine (BT), or the like. In addition, a molding material such as epoxy molding compound (EMC) or a photosensitive material such as photoimageable encapsulant (PIE) may be used.

The redistribution structure 370 may be disposed on the lower portion of the photonic integrated circuit chip 310. The redistribution structure 370 may be a structure for electrically connecting the photonic integrated circuit chip 310 and the second package substrate 200. The redistribution structure 370 may be provided over a wiring layer 220 of the second package substrate 200. According to some embodiments, the redistribution structure 370 may include a redistribution insulating layer 372 and a redistribution pattern 374. The redistribution insulating layer 372 may be provided by being stacked in the vertical direction (Z direction), and the redistribution pattern 374 may be provided within the redistribution insulating layer 372. The redistribution insulating layer 372 may be configured to include a PID or a photosensitive polyimide (PSPI), and the redistribution pattern 374 may be configured to include a metal or a metal alloy such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), but is not limited thereto. In some embodiments, the redistribution pattern may be formed by depositing a metal or a metal alloy on a seed layer including copper, titanium, titanium nitride, or titanium tungsten. The photonic integrated circuit chip 310 and the second package substrate 200 may transmit and receive electrical signals through the redistribution pattern 374 of the redistribution structure 370.

The connection terminal 380 may be disposed on the lower surface of the redistribution structure 370. The connection terminal 380 may include a chip pad 382 disposed along a horizontal direction (X direction and/or Y direction) on the lower surface of the redistribution structure 370 and a chip bump 384 disposed on the chip pad 382.

The chip pad 382 may be disposed on the lower surface of the redistribution structure 370 and may provide a terminal on which the chip bump 384 is disposed. In an embodiment, a material of the chip pad 382 may include aluminum (Al). However, without being limited to the above, the material of the chip pad 382 may include a metal such as nickel (Ni), copper (Cu), gold (Au), silver (Ag), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), ruthenium (Ru), or an alloy thereof.

The chip bump 384 may serve as a terminal for electrically connecting the photonic chip structure 300 to the second package substrate 200. In an embodiment, the chip bump 384 may include solder of a metal material including at least one of tin (Sn), silver (Ag), copper (Cu), and aluminum (Al).

The photonic chip structure 300 described above may be disposed over the first package substrate 100 by way of the second package substrate 200 together with the first chip structure 400 and the second chip structure 500. Hereinafter, the first package substrate 100, the second package substrate 200, the first chip structure 400, the second chip structure 500, and the package molding layer 600 will be described in order.

The first package substrate 100 may include a substrate on which the second package substrate 200 is mounted. In some embodiments, the first package substrate 100 may include a motherboard on which various types of semiconductor chips and packages are mounted. In addition, in some embodiments, the first package substrate 100 may serve as a substrate that receives an electrical signal from the second package substrate 200 and delivers it to an external device.

According to some embodiments, the first package substrate 100 may include a printed circuit board (PCB) including a wiring pattern and an insulating layer surrounding the wiring pattern therein. In this case, the wiring pattern may include copper, nickel, stainless steel, or beryllium copper, and the insulating layer may include at least one material selected from among phenol resin, epoxy resin, and polyimide. The insulating layer may include, for example, at least one material selected from among FR-4, tetrafunctional epoxy, polyphenylene ether, epoxy/polyphenylene oxide, BT, Thermount, cyanate ester, polyimide, and liquid crystal polymer.

The second package substrate 200 may be mounted on the first package substrate 100. The first chip structure 400, the second chip structure 500, and the photonic chip structure 300 may be mounted over an upper surface of the second package substrate 200. The second package substrate 200 may electrically connect the first chip structure 400, the second chip structure 500, and the photonic chip structure 300 to each other. In addition, the second package substrate 200 may be electrically connected to the first package substrate 100 via connection terminals 230. The second package substrate 200 may electrically connect the first chip structure 400, the second chip structure 500, and the photonic chip structure 300 to the first package substrate 100.

In some embodiments, the second package substrate 200 may include an interposer substrate. The second package substrate 200 may include a body layer 210 and the wiring layer 220. The wiring layer 220 may be disposed on an upper surface of the body layer 210. Through electrodes 215 may be formed within the body layer 210. Each of the through electrodes 215 may penetrate the body layer 210 in the vertical direction (Z direction). According to some embodiments, each of the through electrodes 215 may include a through-silicon via (TSV). The wiring layer 220 may include a wiring pattern 225. The wiring pattern 225 may electrically connect the first chip structure 400, the second chip structure 500, and the photonic chip structure 300 to each other, or may electrically connect the first chip structure 400, the second chip structure 500, and the photonic chip structure 300, or may electrically connect between the first chip structure 400 and the through electrodes 215, between the second chip structure 500 and the through electrodes 215, and between the photonic chip structure 300 and the through electrodes 215. Each of the through electrodes 215 may be electrically connected to the first package substrate 100 through a pad and a bump formed on a lower surface of the body layer 210.

Although the second package substrate 200 has been described as a silicon interposer including the TSV, it is not limited thereto, and the second package substrate 200 may also be a glass interposer including a through-glass via (TGV).

In addition, in some embodiments, the second package substrate 200 may include a redistribution structure including a redistribution pattern and a redistribution insulating layer surrounding the redistribution pattern. The redistribution insulating layer may include an insulating material, for example, a PID resin. In some embodiments, the redistribution insulating layer may further include an inorganic filler. In some embodiments, the redistribution insulating layer may include a multilayer structure in which the redistribution pattern is disposed in each layer. The redistribution pattern may include a redistribution line pattern extending in the horizontal direction and a redistribution via pattern extending in a vertical direction (Z direction) from the redistribution line pattern. The redistribution line pattern may be disposed on at least one of an upper surface and a lower surface of the redistribution insulating layer or within the redistribution insulating layer. The redistribution via pattern may penetrate the redistribution insulating layer and be connected to a portion of the redistribution line pattern. The redistribution pattern may include a conductive material, for example, copper (Cu), aluminum (Al), silver (Ag), tin (Sn), gold (Au), nickel (Ni), lead (Pb), titanium (Ti), or an alloy thereof.

The photonic chip structure 300, the first chip structure 400, and the second chip structure 500 may be mounted over the upper surface of the second package substrate 200. According to an embodiment, the photonic chip structure 300 may be located at an outer portion of the upper surface of the second package substrate 200.

In some embodiments, the first chip structure 400 may be located adjacent to a central portion of the upper surface of the second package substrate 200, and the second chip structure 500 may be arranged on both sides of the first chip structure 400 while being spaced apart from the first chip structure 400 in the first horizontal direction (X direction). The photonic chip structure 300 may be arranged spaced apart from the first chip structure 400 in a second horizontal direction (Y direction).

In FIG. 1, although the semiconductor package 10 is illustrated as including one first chip structure 400, four second chip structures 500, and four photonic chip structures 300, the numbers of the first chip structure 400, the second chip structure 500, and the photonic chip structure 300 included in the semiconductor package 10 are not limited thereto. Also, for example, the semiconductor package 10 may include only one of the first chip structure 400 and the second chip structure 500.

The first chip structure 400 may include a first chip body 410, a first chip pad 420, and a first chip bump 430. In the present specification, the first chip structure 400 may include a non-memory chip structure including a non-memory element. The first chip body 410 may include, for example, silicon. Alternatively, the first chip body 410 may include a semiconductor element such as germanium, or a compound semiconductor such as silicon carbide (SiC), gallium arsenide (GaAs), indium arsenide (InAs), or indium phosphide (InP). Alternatively, the first chip body 410 may include a silicon on insulator (SOI) structure. For example, the first chip body 410 may include a BOX layer. The first chip body 410 may include a conductive region, for example, a well doped with impurities or a structure doped with impurities. In addition, the first chip body 410 may have various element isolation structures such as a shallow trench isolation (STI) structure.

The first chip structure 400 may be, for example, a system-on-chip, a central processing unit (CPU) chip, a graphics processing unit (GPU) chip, or an application processor (AP) chip. The first chip structure 400 may execute applications supported by the semiconductor package 10 using a memory device included in the second chip structure 500. For example, the first chip structure 400 may execute specialized operations by including at least one processor selected from a central processing unit (CPU), an application processor (AP), a graphics processing unit (GPU), a neural processing unit (NPU), a tensor processing unit (TPU), a vision processing unit (VPU), an image signal processor (ISP), and a digital signal processor (DSP).

According to an embodiment, a plurality of first chip pads 420 may be arranged in the horizontal direction (X direction and/or Y direction) on a lower surface of the first chip body 410. According to an embodiment, an upper surface of the first chip pad 420 may be co-planar with a lower surface of the first chip body 410, and the first chip pad 420 may be in contact with the first chip bump 430. The first chip pad 420 may receive electrical signals from the second chip structure 500 or the photonic chip structure 300 through the second package substrate 200, or may transmit electrical signals to the second chip structure 500 or the photonic chip structure 300.

The first chip pad 420 may include a conductive material that may include, for example, copper (Cu), gold (Au), silver (Ag), nickel (Ni), tungsten (W), aluminum (Al), or a combination thereof. In some embodiments, the first chip pad 420 may further include a barrier material to prevent the conductive material from diffusing outside the first chip pad 420. The barrier material may include, for example, titanium (Ti), tantalum (Ta), titanium nitride (TiN), tantalum nitride (TaN), or a combination thereof.

According to an embodiment, a plurality of first chip bumps 430 may be attached to the plurality of first chip pads 420 of the first chip body 410. The first chip bump 430 may be configured to include a conductive material such as tin (Sn), lead (Pb), silver (Ag), copper (Cu), or a combination thereof. The first chip bump 430 may be formed by using, for example, solder balls. The first chip bump 430 may be configured to connect the first chip structure 400 to the second package substrate 200.

According to some embodiments, a first underfill material layer 440 may be further disposed on the lower surface of the first chip body 410. The first underfill material layer 440 may be arranged to surround the first chip bump 430 between the second package substrate 200 and the first chip structure 400. For example, the first underfill material layer 440 may be formed by any one of a capillary underfill process, a no-flow underfill process, a molded underfill process, and a NCF process. The first underfill material layer 440 may have a tapered shape in which a horizontal width decreases along the vertical direction (Z direction) from the second package substrate 200 toward the first chip body 410.

The second chip structure 500 may include a second chip body 510, a second chip pad 520, and a second chip bump 530. In the present specification, the second chip structure 500 may serve as a memory chip structure including a memory element. The second chip body 510 may include, for example, silicon. Alternatively, the second chip body 510 may include a semiconductor element such as germanium, or a compound semiconductor such as silicon carbide (SiC), gallium arsenide (GaAs), indium arsenide (InAs), or indium phosphide (InP). Alternatively, the second chip body 510 may have a SOI structure. For example, the second chip body 510 may include a BOX layer. The second chip body 510 may include a conductive region, for example, a well doped with impurities or a structure doped with impurities. In addition, the second chip body 510 may have various element isolation structures such as a STI structure.

The second chip structure 500 may be, for example, a dynamic random access memory (DRAM), a static random access memory (SRAM), a flash memory, an electrically erasable and programmable read-only memory (EEPROM), a phase-change random access memory (PRAM), a magnetic random access memory (MRAM), or a resistive random access memory (RRAM). According to an example embodiment, the second chip structure 500 may include a memory cell chip having cells of high bandwidth memory (HBM) DRAM.

According to an embodiment, a plurality of second chip pads 520 may be arranged in a lateral direction (X direction and/or Y direction) on a lower surface of the second chip body 510. According to an embodiment, an upper surface of the second chip pad 520 may be co-planar with the lower surface of the second chip body 510, and the second chip pad 520 may be in contact with the second chip bump 530. The second chip pad 520 may receive electrical signals from the first chip structure 400 or the photonic chip structure 300 through the second package substrate 200, or may transmit electrical signals to the first chip structure 400 or the photonic chip structure 300.

The second chip pad 520 may be configured to include a conductive material such as copper (Cu), gold (Au), silver (Ag), nickel (Ni), tungsten (W), aluminum (Al), or a combination thereof. In some embodiments, the second chip pad 520 may further include a barrier material to prevent the conductive material from diffusing outside the second chip pad 520. The barrier material may include, for example, titanium (Ti), tantalum (Ta), titanium nitride (TiN), tantalum nitride (TaN), or a combination thereof.

According to an embodiment, a plurality of second chip bumps 530 may be attached to the plurality of second chip pads 520 of the second chip body 510. The second chip bump 530 may be configured to include a conductive material such as tin (Sn), lead (Pb), silver (Ag), copper (Cu), or a combination thereof. The second chip bump 530 may be formed by using, for example, solder balls. The second chip bump 530 may be configured to connect the second chip structure 500 to the second package substrate 200.

According to some embodiments, a second underfill material layer 540 may be further disposed on the lower surface of the second chip body 510. The second underfill material layer 540 may be arranged to surround the second chip bump 530 between the second package substrate 200 and the second chip structure 500. For example, the second underfill material layer 540 may be formed by any one of a capillary underfill process, a no-flow underfill process, a molded underfill process, and a NCF process. The second underfill material layer 540 may have a tapered shape in which a horizontal width decreases along the vertical direction (Z direction) from the second package substrate 200 toward the second chip body 510.

Although the first chip structure 400 and the second chip structure 500 have been described respectively as the non-memory chip structure and the memory chip structure, this is not limited thereto. In some embodiments, the first chip structure 400 may be a memory chip structure including a memory chip, and the second chip structure 500 may be a non-memory chip structure including a non-memory element.

The photonic chip structure 300 as described above may be mounted on the second package substrate 200 to be spaced apart from both the first chip structure 400 and the second chip structure 500 in the horizontal direction (e.g., the X direction and/or the Y direction). In some embodiments, the photonic chip structure 300 may be mounted on the second package substrate 200 in a flip-chip manner through the connection terminal 380 such as the chip bump. According to some embodiments, an underfill material layer 390 surrounding the connection terminal 380 may be located between the photonic chip structure 300 and the second package substrate 200. The underfill material layer 390 may have substantially a same configuration as the first underfill material layer 440 and the second underfill material layer 540 described in the first chip structure 400 and the second chip structure 500.

The package molding layer 600 may be formed to surround the first chip structure 400, the second chip structure 500, and the photonic chip structure 300 on the upper surface of the second package substrate 200. In some embodiments, the package molding layer 600 may cover the side surfaces of the first chip structure 400, the second chip structure 500, and the photonic chip structure 300, and may not cover the upper surfaces of the first chip structure 400, the second chip structure 500, and the photonic chip structure 300. In this case, an upper surface of the package molding layer 600 may be co-planar with upper surfaces of the first chip structure 400, the second chip structure 500, and the photonic chip structure 300. Likewise, the upper surface of the package molding layer 600 may be located on a same vertical level as the upper surfaces of the first chip structure 400, the second chip structure 500, and the photonic chip structure 300.

According to example embodiments, package molding layer 600 may include a thermosetting resin such as epoxy resin, a thermoplastic resin such as polyimide resin, or a resin including reinforcing materials such as inorganic fillers, and specifically, may include ABF, FR-4, or BT, but is not limited thereto and may further include a molding compound such as EMC or a photosensitive material such as PIE. In some embodiments, a portion of the package molding layer 600 may include an insulating material such as a silicon oxide film, a silicon nitride film, or a silicon oxynitride film.

In some embodiments, the package molding layer 600 may be filled in gaps between the first chip structure 400, the second chip structure 500, and the photonic chip structure 300 and the second package substrate 200 through a molded under-fill process. In such a case, the first underfill material layer 440, the second underfill material layer 540, and the underfill material layer 390 may each be omitted.

In FIGS. 1 and 3, the photonic chip structure 300 of FIG. 4 is illustrated as being mounted, but is not limited thereto. For example, various embodiments of the photonic chip structure described below may be mounted in FIGS. 1 and 3.

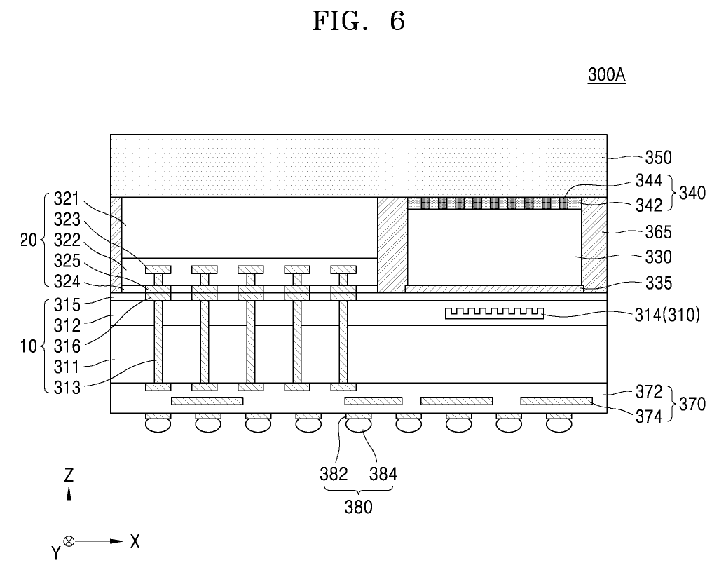

FIG. 6 is a cross-sectional view schematically illustrating a photonic chip structure 300A according to an embodiment.

The photonic chip structure 300A described in FIG. 6 is an embodiment of the photonic chip structure illustrated in FIGS. 1 and 3, and, except for the protective layer 350 and a gap-filling layer 365, most of the components constituting the embodiment and the materials included in those components are the same as or similar to those described in FIG. 4. Therefore, for convenience of explanation, a description will be given focusing on the differences from the photonic chip structure 300 described in FIG. 4.

Referring to FIG. 6, the photonic chip structure 300A may include the photonic integrated circuit chip 310, the electronic integrated circuit chip 320, the optical block 330, the metalens 340, the protective layer 350, the gap-filling layer 365, the redistribution structure 370, and the connection terminal 380.

According to some embodiments, the upper surface of the electronic integrated circuit chip 320 may be disposed to be located on a same vertical level as the upper surface of the metalens 340. The protective layer 350 may be disposed to span the upper surface of the metalens 340 and the upper surface of the electronic integrated circuit chip 320. For example, the protective layer 350 may be formed to entirely cover the upper surface of the metalens 340 and the upper surface of the electronic integrated circuit chip 320.

The gap-filling layer 365 may be formed to surround the electronic integrated circuit chip 320, the optical block 330, and the metalens 340 between the photonic integrated circuit chip 310 and the protective layer 350. The gap-filling layer 365 may surround the side surface of the electronic integrated circuit chip 320, the side surface of the optical block 330, and the side surface of the metalens 340 between the upper surface of the first passivation layer 315 of the photonic integrated circuit chip 310 and the lower surface of the protective layer 350. The gap-filling layer 365 may include, for example, SiO₂.

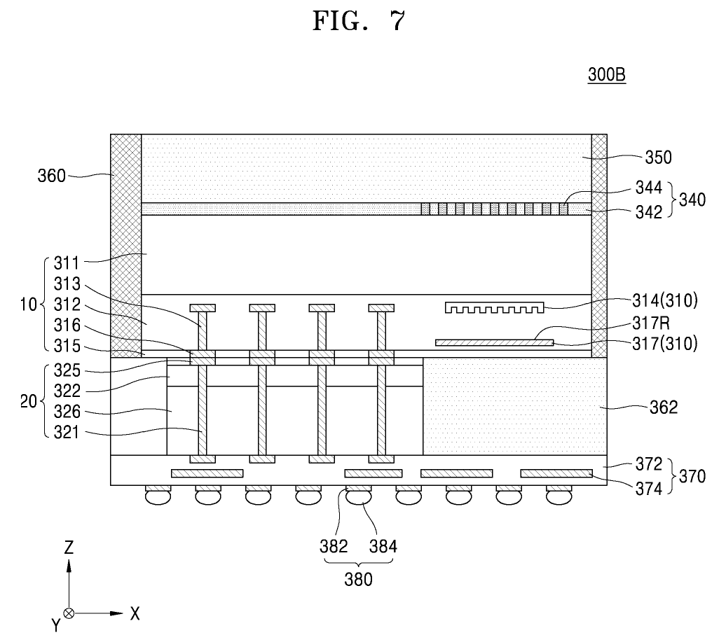

FIG. 7 is a cross-sectional view schematically illustrating a photonic chip structure 300B according to an embodiment.

The photonic chip structure 300B described in FIG. 7 is an embodiment of the photonic chip structure illustrated in FIGS. 1 and 3, and, except for a direction of the active surface of the photonic integrated circuit chip 310, a placement of the electronic integrated circuit chip 320, a point that a reflective structure 317 is included but the optical block is omitted, most of the components constituting the embodiment and the materials included in those components are the same as or similar to those described in FIG. 4. Therefore, for convenience of explanation, a description will be given focusing on the differences from the photonic chip structure 300 described in FIG. 4.

Referring to FIG. 7, the photonic chip structure 300B may include the photonic integrated circuit chip 310, the optical coupler 314, the reflective structure 317, the electronic integrated circuit chip 320, the metalens 340, the protective layer 350, the molding layer 360, the redistribution structure 370, and the connection terminal 380.

According to an embodiment, the photonic integrated circuit chip 310 may be arranged such that the active surface faces downward. Accordingly, the electronic integrated circuit chip 320 may be disposed on the lower portion of the photonic integrated circuit chip 310.

A molding layer 362 may be located between the redistribution structure 370 and the photonic integrated circuit chip 310 to surround the electronic integrated circuit chip 320. The molding layer 362 may include, for example, a thermosetting resin such as epoxy resin, a thermoplastic resin such as polyimide, or a resin including an inorganic filler therein, and specifically may include ABF, FR-4, BT, or the like. In addition, the molding material such as EMC or the photosensitive material such as PIE may be used.

The optical coupler 314 may be placed within the first interlayer insulating layer 312 of the photonic integrated circuit chip 310, and the first substrate 311 may be disposed on an upper portion the first interlayer insulating layer 312. Because the active surface of the photonic integrated circuit chip 310 faces downward, the optical coupler 314 of the photonic integrated circuit chip 310 may be positioned relatively lower in the vertical direction (Z direction) compared to the optical coupler of FIG. 4. The optical coupler 314 may be arranged in a direction facing the active surface of the photonic integrated circuit chip 310. For example, the optical coupler 314 may be arranged to face the lower surface of the photonic integrated circuit chip 310.

The reflective structure 317 may be positioned beneath the optical coupler 314 within the first interlayer insulating layer 312. For example, the reflective structure 317 may be arranged to be located at a side opposite to the metalens 340 with respect to the optical coupler 314. The reflective structure 317 may be arranged such that the reflective surface 317R of the reflective structure317 faces the upper surface of the photonic integrated circuit chip 310. The reflective structure 317 may be arranged such that the reflective surface 317R faces the optical coupler 314. The reflective structure 317 may include, for example, a reflective mirror.

The metalens 340 may be disposed on an upper portion, which is an inactive surface, of the photonic integrated circuit chip 310. The metalens 340 may be directly coupled on the photonic integrated circuit chip 310.

The metalens 340 may include the planar portion 342 and the plurality of nano-structures 344. The planar portion 342 may be disposed to span the upper surface of the photonic integrated circuit chip 310. The planar portion 342 may be disposed to entirely cover the upper surface of the photonic integrated circuit chip 310. The planar portion 342 may include a material with a relatively low first refractive index n1.

The plurality of nano-structures 344 may be disposed in an area overlapping the optical coupler 314 in a vertical direction and in a peripheral area thereof within an entire area of the planar portion 342. The plurality of nano-structures 344 may be disposed on the planar portion 342 such that optical signals passing through the metalens 340 are delivered to the optical coupler 314. The plurality of nano-structures 344 may include a material having a relatively high second refractive index n2. In some embodiments, the ratio of the first refractive index n1 to the second refractive index n2 may be greater than 1.2 and less than 5.

The metalens 340 and the optical coupler 314 may be arranged such that a distance therebetween is greater than 100 μm. Because the first substrate 311 of the photonic integrated circuit chip 310 is located between the optical coupler 314 and the metalens 340, a sufficient distance may be secured between the metalens 340 and the optical coupler 314, and the optical block may be omitted.

The protective layer 350 may be disposed to entirely cover the upper surface of the metalens 340. For example, the protective layer 350 may be coupled to the upper surface of the metalens 340 by oxide bonding. However, such coupling is not limited thereto, and the protective layer 350 may also be coupled to the metalens 340 by using optical glue.

The FAU (in FIG. 3), the protective layer 350, the metalens 340, the optical coupler 314, and the reflective structure 317 may be disposed to vertically overlap one another. Accordingly, optical signals output from the FAU may sequentially pass through the protective layer 350, the metalens 340, and the first substrate 311, and may be reflected by the reflective surface 317R of the reflective structure 317 to be delivered to the optical coupler 314.

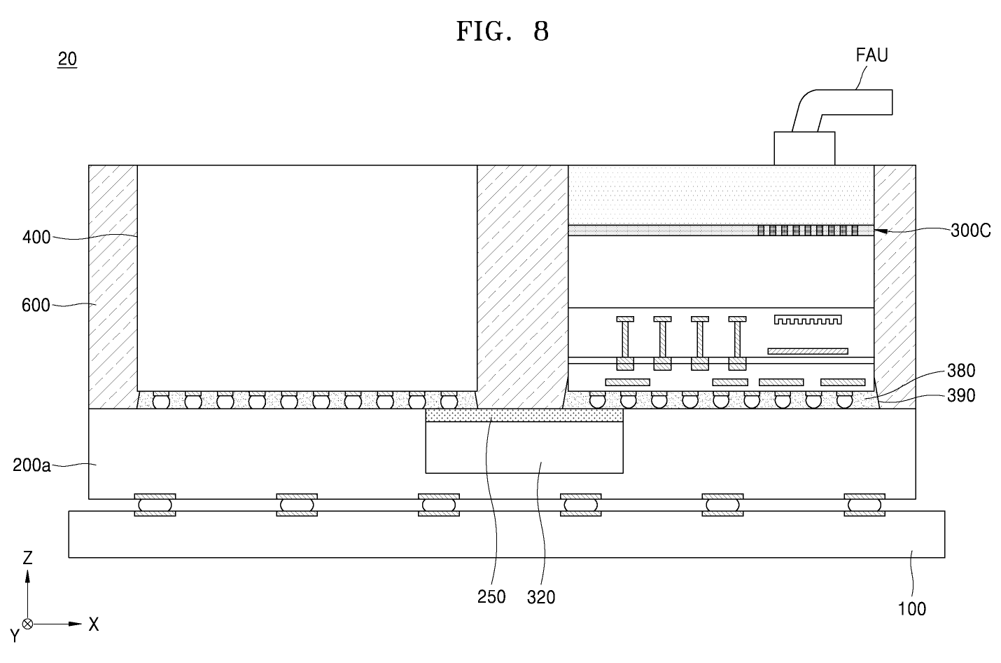

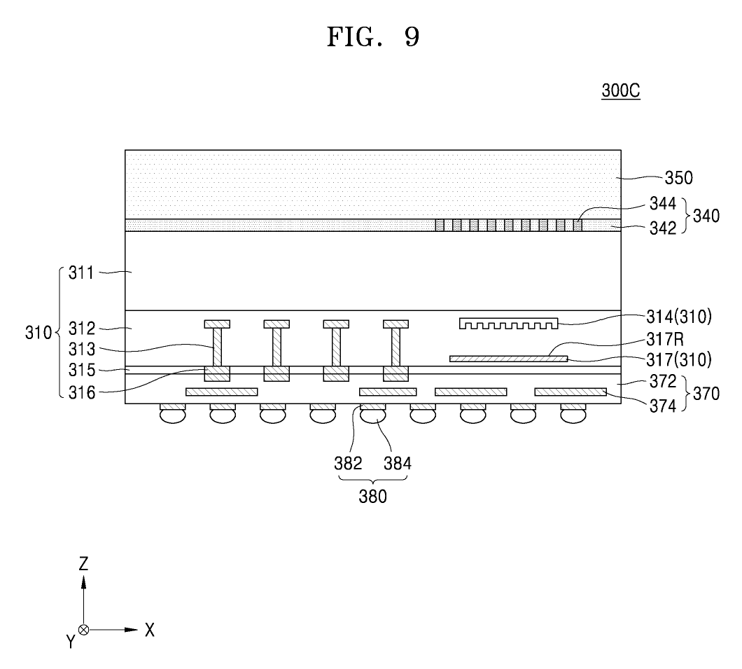

FIG. 8 is a cross-sectional view schematically illustrating a semiconductor package 20 according to an embodiment. FIG. 9 is a cross-sectional view schematically illustrating a photonic chip structure 300C according to an embodiment.

Most of the components of the semiconductor package 20 of FIG. 8 and the materials constituting those components are the same or similar to those described in FIGS. 1 - 3, except for the positions of the second package substrate 200a and the electronic integrated circuit chip 320. The photonic chip structure 300C of FIG. 9 is an enlarged view of the photonic chip structure 300C included in the semiconductor package 20 of FIG. 8 and is the same or similar to what is described in FIG. 7. For convenience of explanation, a description will be given focusing on differences.

Referring to FIG. 8, the semiconductor package 20 may include the first package substrate 100, a second package substrate 200a, the photonic chip structure 300C, the first chip structure 400, and the package molding layer 600.

The second package substrate 200a may be mounted on the first package substrate 100. The first chip structure 400 and the photonic chip structure 300C may be mounted over the upper surface of the second package substrate 200a.

In a partial region of the second package substrate 200a, a silicon bridge 250 and the electronic integrated circuit chip 320 may be disposed in an inserted state. The silicon bridge 250 may include fine wirings and may electrically connect the first chip structure 400, the photonic chip structure 300C, and the electronic integrated circuit chip 320 to one another.

Referring to FIG. 9, the photonic chip structure 300C may include the photonic integrated circuit chip 310, the metalens 340, the protective layer 350, the redistribution structure 370, and the connection terminal 380.

According to an example embodiment, the photonic integrated circuit chip 310 may be disposed such that the active surface faces downward.

The optical coupler 314 may be disposed within the first interlayer insulating layer 312 of the photonic integrated circuit chip 310, and the first substrate 311 may be disposed on the first interlayer insulating layer 312. Because the active surface of the photonic integrated circuit chip 310 faces downward, the optical coupler 314 of the photonic integrated circuit chip 310 may be positioned relatively lower in the vertical direction (Z direction) compared to the optical coupler of FIG. 4. The optical coupler 314 may be arranged in a direction facing the active surface of the photonic integrated circuit chip 310. For example, the optical coupler 314 may be arranged to face the lower surface of the photonic integrated circuit chip 310.

The reflective structure 317 may be positioned beneath the optical coupler 314 within the first interlayer insulating layer 312. For example, the reflective structure 317 may be arranged to be located at a side opposite to the metalens 340 with respect to the optical coupler 314. The reflective structure 317 may be arranged such that the reflective surface 317R of the reflective structure 317 faces the upper surface of the photonic integrated circuit chip 310. The reflective structure 317 may be arranged such that the reflective surface 317R faces the optical coupler 314.

The metalens 340 may be disposed on an upper portion, which is an inactive surface, of the photonic integrated circuit chip 310. The metalens 340 may be directly coupled on the photonic integrated circuit chip 310.

The protective layer 350 may be disposed to cover the entire upper surface of the metalens 340.

The FAU, the protective layer 350, the metalens 340, the optical coupler 314, and the reflective structure 317 may be disposed to vertically overlap one another. Accordingly, optical signals output from the FAU may sequentially pass through the protective layer 350, the metalens 340, and the first substrate 311, and may be reflected by the reflective surface 317R of the reflective structure 317 to be delivered to the optical coupler 314.

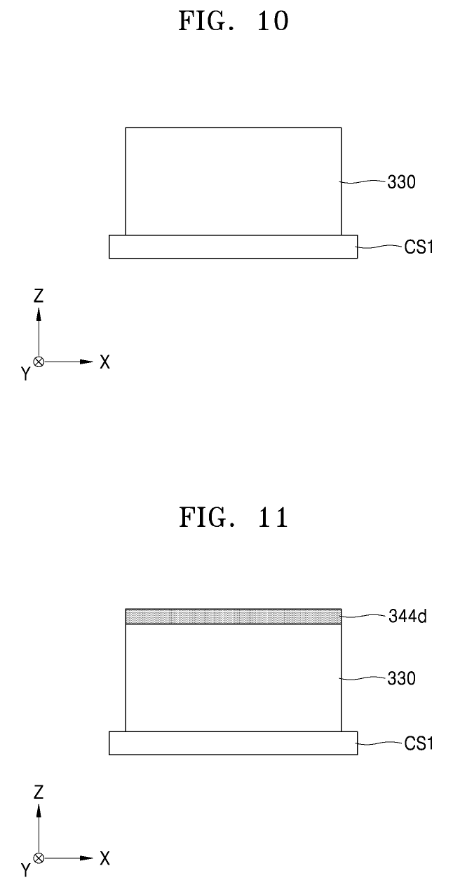

FIGS. 10 - 24 are diagrams schematically illustrating a process of manufacturing the semiconductor package 10 according to FIGS. 1 - 4. Here, FIGS. 10 - 18 are diagrams schematically illustrating processes of forming the metalens 340 and the protective layer 350 on the optical block 330.

Referring to FIG. 10, the optical block 330 is prepared by being attached to a carrier substrate CS1.

Referring to FIG. 11, a nano-structure layer 344d is deposited on the upper surface of the optical block 330.

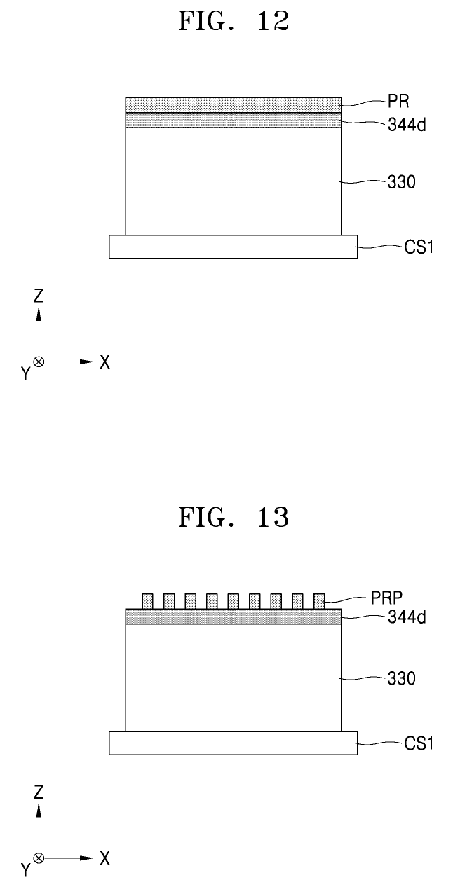

Referring to FIG. 12, a photoresist layer PR is formed on the nano-structure layer 344d. The photoresist layer PR is a photosensitive material, of which the chemical properties are changed when exposed to light (for example, ultraviolet light or laser), and is thus selectively removable in a subsequent process. For example, the photoresist layer PR may be formed of a composite material including a polymer material.

Referring to FIG. 13, a plurality of photoresist patterns PRP are formed on the nano-structure layer 344d. In the result of FIG. 12, the photoresist layer PR is exposed and developed to form the photoresist patterns PRP.

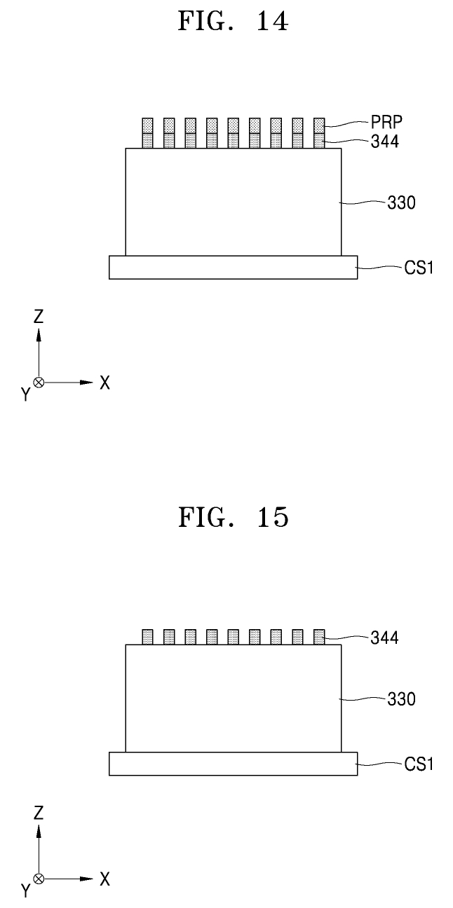

Referring to FIGS. 14 and 15, the nano-structure layer 344d is etched along the photoresist patterns PRP in the result of FIG. 13 by using plasma etching or the like, to form the nano-structures 344. Thereafter, the photoresist patterns PRP are removed. For example, the nano-structures 344 may include TiO₂.

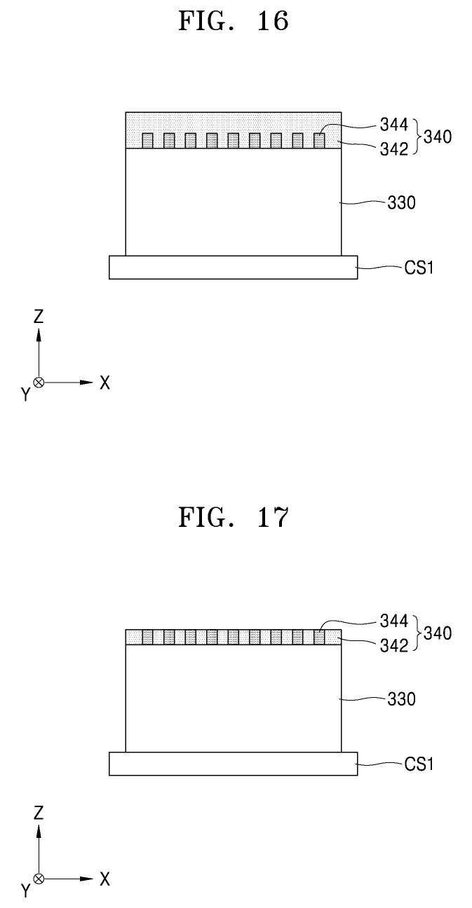

Referring to FIGS. 16 and 17, in the result of FIG. 15, the planar portion 342 is deposited to fill spaces between the nano-structures 344. The planar portion 342 may include, for example, SiO₂. Thereafter, the planar portion 342 is ground so that the nano-structures 344 are exposed, and the metalens 340 can be formed on the optical block 330. For example, the planar portion 342 may be polished through chemical mechanical polishing (CMP).

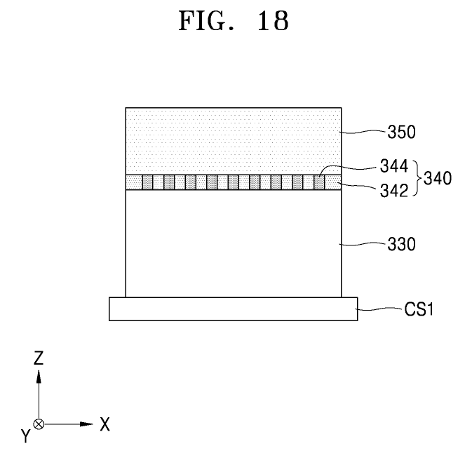

Referring to FIG. 18, in the result of FIG. 17, the protective layer 350 is attached to the upper surface of the metalens 340. For example, the protective layer 350 may be coupled to the upper surface of the metalens 340 by oxide bonding. Thereafter, the optical block 330 is separated from the carrier substrate CS1.

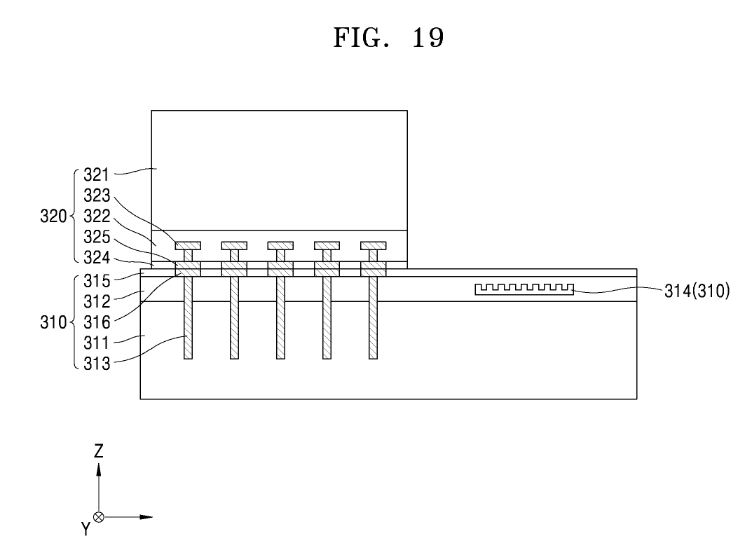

Referring to FIG. 19, the photonic integrated circuit chip 310 is prepared, and the electronic integrated circuit chip 320 is attached on the photonic integrated circuit chip 310. The electronic integrated circuit chip 320 may be attached on the photonic integrated circuit chip 310 in a face-down manner such that the active surface and the wiring structure 323 of the electronic integrated circuit chip 320 face the photonic integrated circuit chip 310. The electronic integrated circuit chip 320 may be coupled on the photonic integrated circuit chip 310 such that the second connection pad 325 is coupled to the first connection pad 316 of the photonic integrated circuit chip 310.

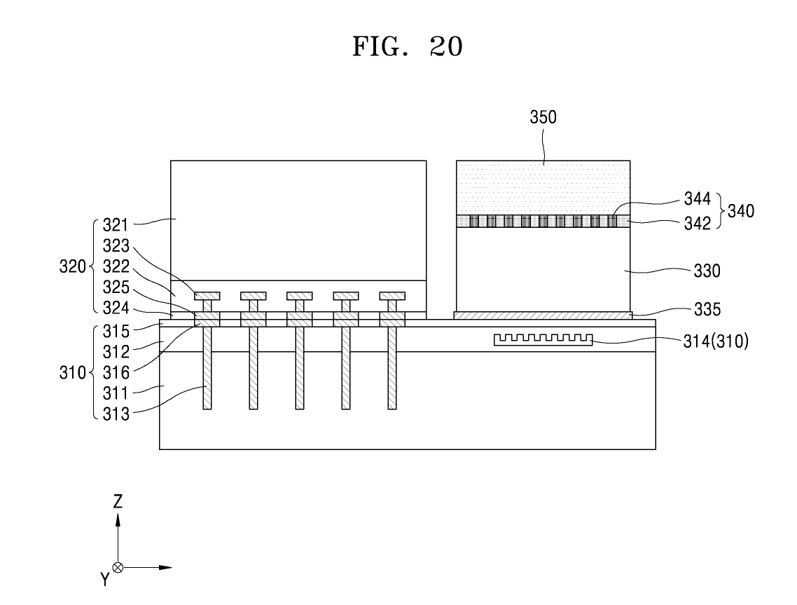

Referring to FIG. 20, the optical block 330 is attached on the photonic integrated circuit chip 310. For example, the optical block 330 in which the metalens 340 and the protective layer 350 are sequentially stacked through FIGS. 10 - 18 may be attached on the photonic integrated circuit chip 310. The optical block 330 may be coupled on the photonic integrated circuit chip 310 by oxide bonding, hybrid bonding, or an optical adhesive layer 335.

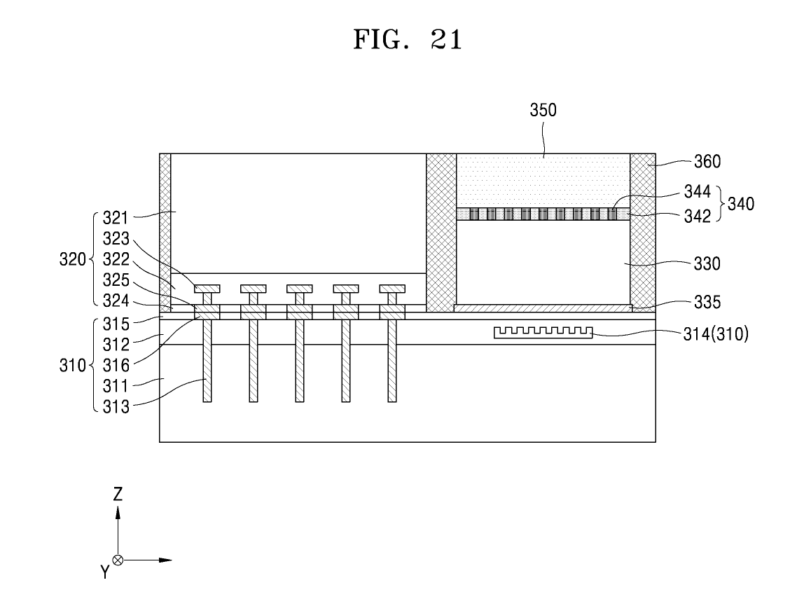

Referring to FIG. 21, the molding layer 360 is formed on the photonic integrated circuit chip 310. The molding layer 360 may seal the electronic integrated circuit chip 320, the optical block 330, the metalens 340, and the protective layer 350 on the photonic integrated circuit chip 310. The molding layer 360 may cover an upper surface of the first passivation layer 315 of the photonic integrated circuit chip 310 and may surround the side surfaces of the electronic integrated circuit chip 320, the optical block 330, the metalens 340, and the protective layer 350.

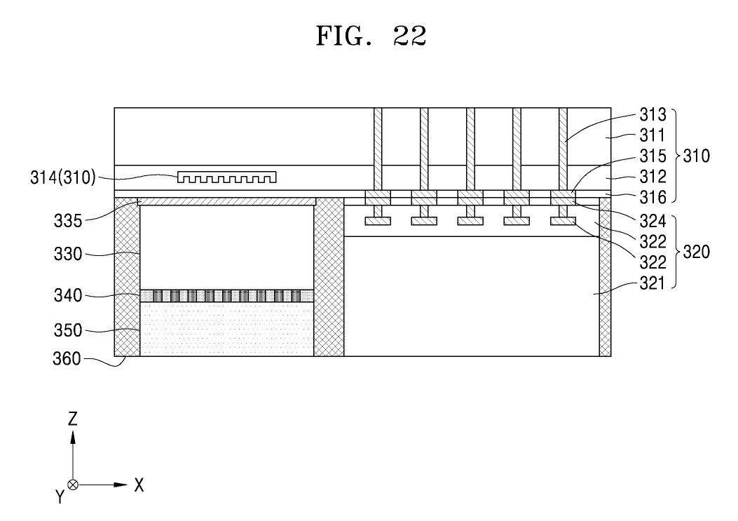

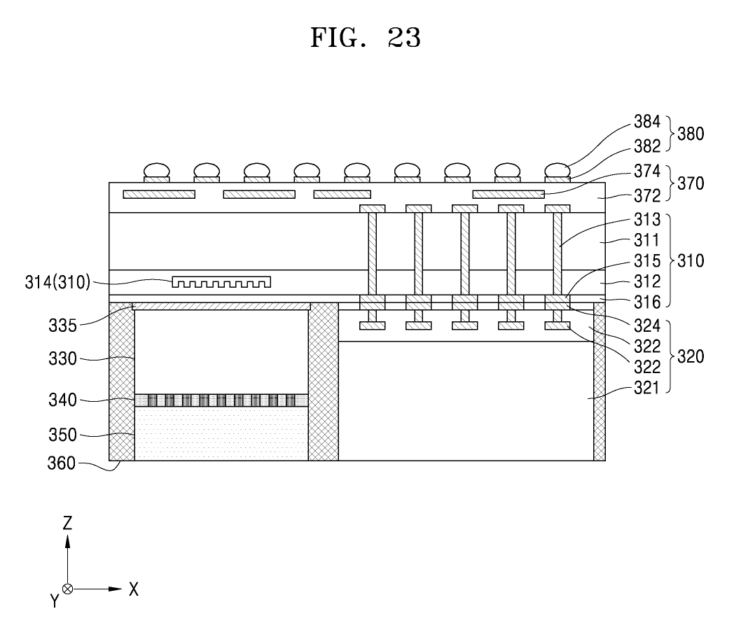

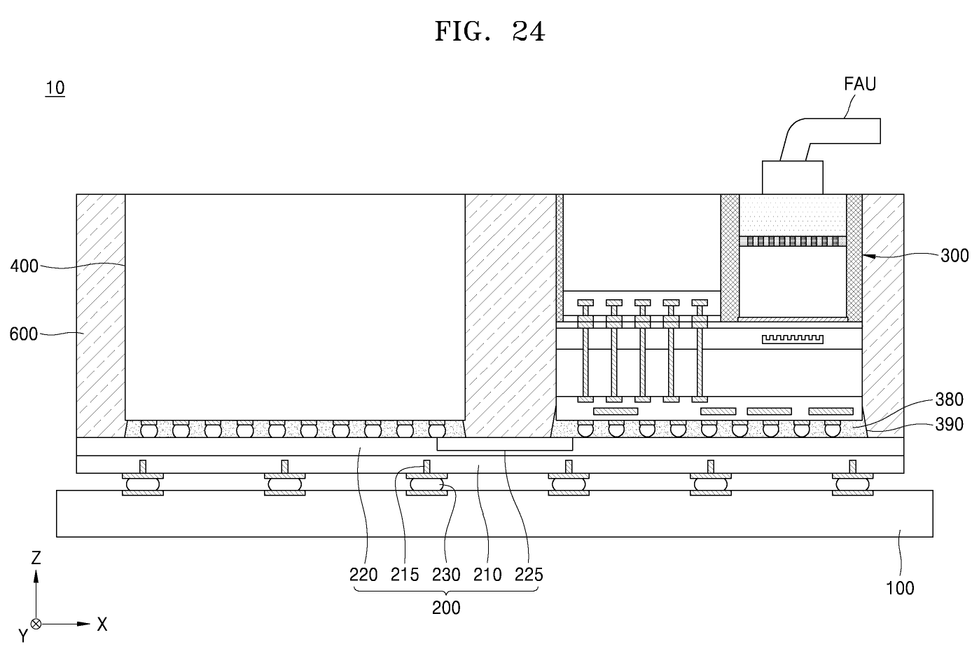

Referring to FIGS. 22 and 23, the photonic chip structure of FIG. 21 is flipped over, and the first substrate 311 of the photonic integrated circuit chip 310 is ground such that the through electrodes 313 are exposed from the first substrate 311. The process of grinding the first substrate 311 may be understood as a back grinding process that thins the first substrate 311. When the through electrodes 313 are exposed from the first substrate 311, the redistribution structure 370 is formed on the first substrate 311. The redistribution structure 370 may include the redistribution insulating layer 372 and the redistribution pattern 374, and the redistribution pattern 374 may be connected to the exposed through electrodes 313. Thereafter, the connection terminals 380 are formed on the redistribution structure 370.

Referring to FIG. 24, the photonic chip structure 300, the first chip structure 400, and the second chip structure 500 of FIG. 23 are mounted on the second package substrate 200. Thereafter, the package molding layer 600 is formed on the second package substrate 200. The package molding layer 600 may cover the first chip structure 400, the second chip structure 500, and the photonic chip structure 300. Thereafter, the second package substrate 200 on which the first chip structure 400, the second chip structure 500, and the photonic chip structure 300 are mounted may be attached on the first package substrate 100.

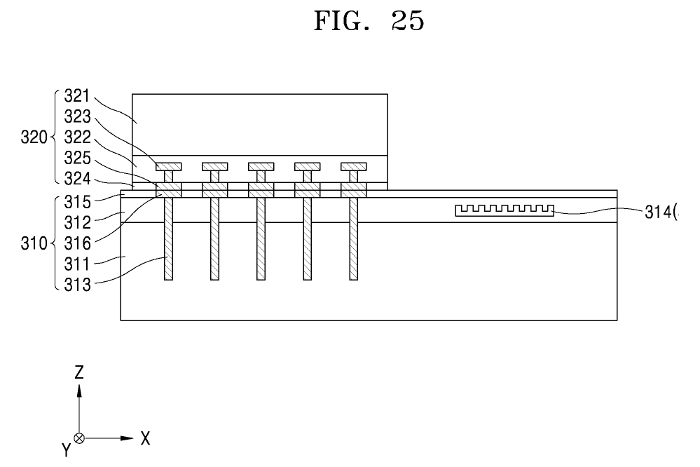

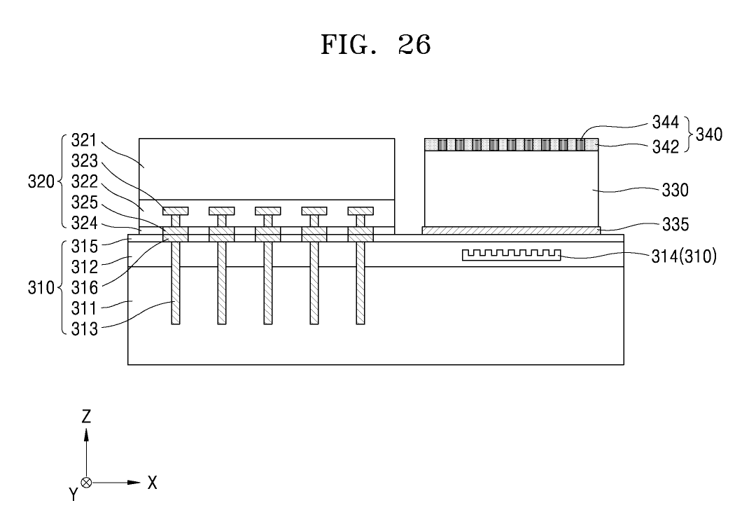

FIGS. 25 - 30 are views schematically illustrating a process of fabricating the photonic chip structure 300C of FIG. 6. The same processes described in FIGS. 10 - 24 will be omitted.

Referring to FIG. 25, the photonic integrated circuit chip 310 is prepared, and the electronic integrated circuit chip 320 is attached on the photonic integrated circuit chip 310.

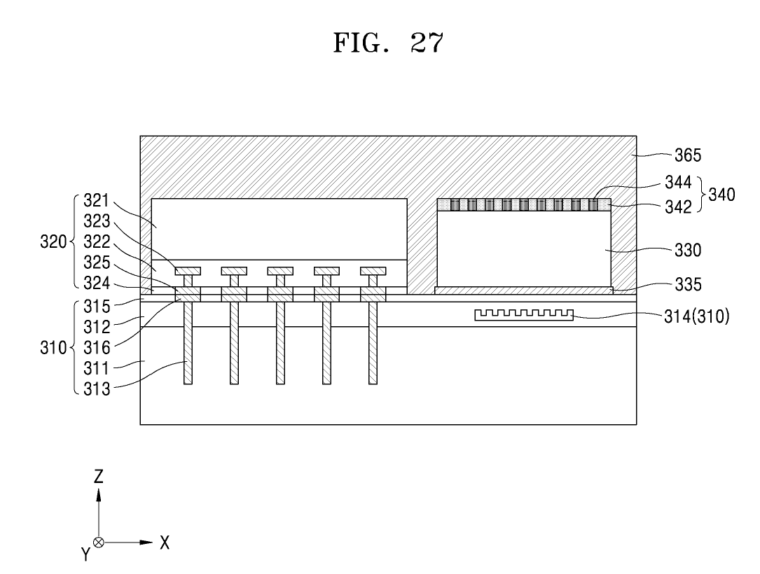

Referring to FIG. 26, the optical block 330 in which the metalens 340 of the result of FIG. 17 is formed is attached on the photonic integrated circuit chip 310. The optical block 330 may be attached on the photonic integrated circuit chip 310 at a position spaced apart in the horizontal direction (X direction and/or Y direction) from the electronic integrated circuit chip 320. For example, the upper surface of the electronic integrated circuit chip 320 and the upper surface of the metalens 340 may be disposed to be located on a same vertical level.

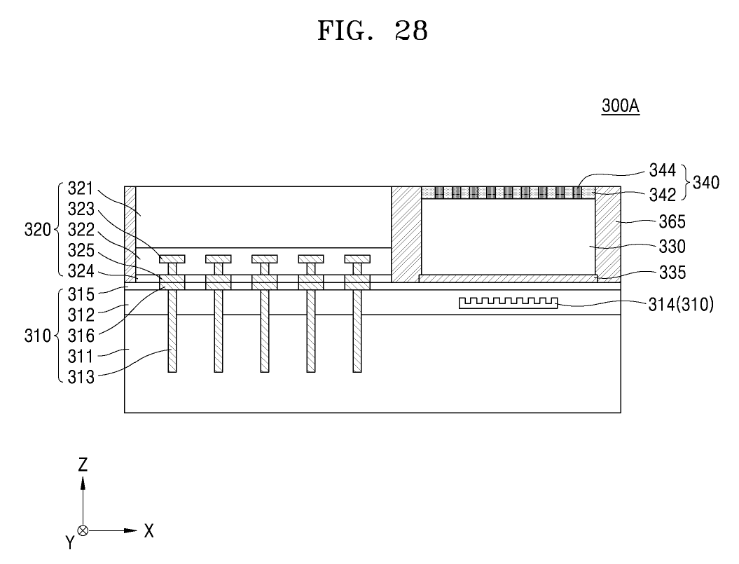

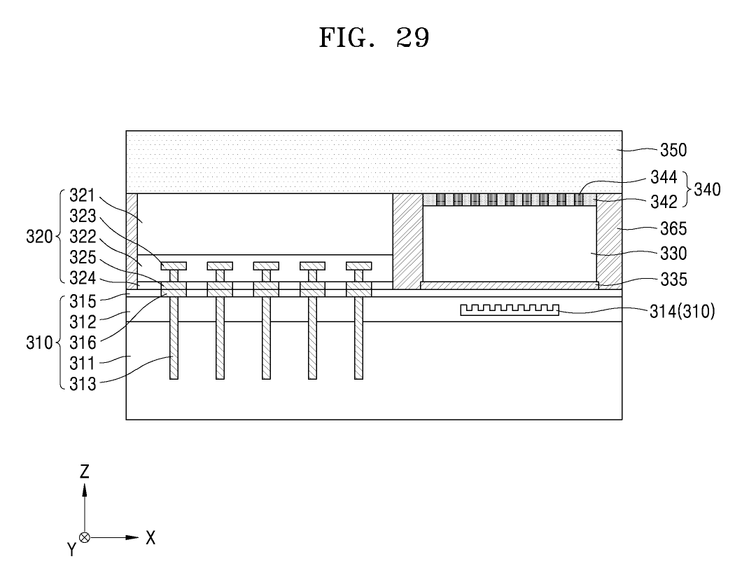

Referring to FIGS. 27 and 28, the gap-filling layer 365 is formed by deposition on the photonic integrated circuit chip 310. For example, the gap-filling layer 365 may be formed by a plasma-enhanced chemical vapor deposition (PECVD) method. The gap-filling layer 365 may surround side surfaces of the electronic integrated circuit chip 320, the optical block 330, and the metalens 340 on the photonic integrated circuit chip 310. For example, the gap-filling layer 365 may include SiO₂. Thereafter, the gap-filling layer 365 is ground so that the upper surface of the metalens 340 is exposed.

Referring to FIG. 29, in the result of FIG. 28, the protective layer 350 is attached on upper surfaces of the electronic integrated circuit chip 320, the metalens 340, and the gap-filling layer 365. For example, the protective layer 350 may be coupled to the upper surface of the metalens 340 by oxide bonding. The protective layer 350 may be formed to entirely cover the upper surface of the electronic integrated circuit chip 320 and the upper surface of the metalens 340.

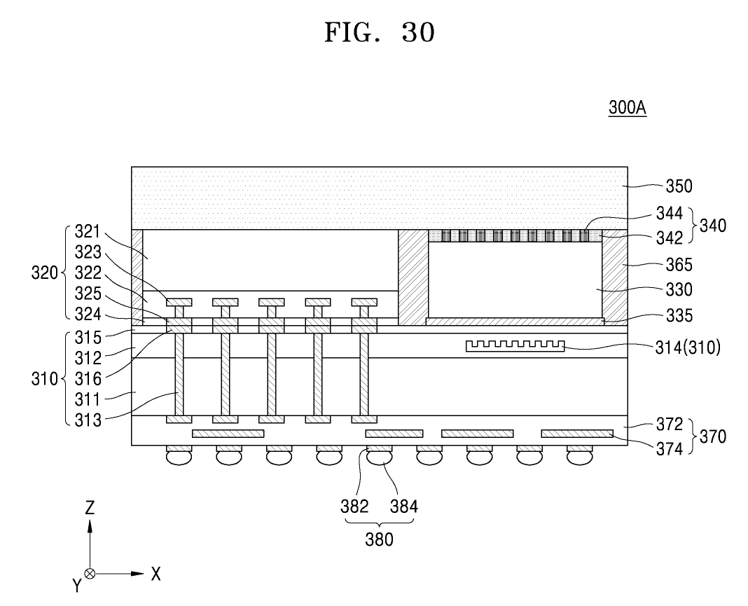

Referring to FIG. 30, in the result of FIG. 29, the photonic chip structure 300B may be fabricated by grinding the first substrate 311 and forming the redistribution structure 370 and the connection terminals 380 through FIGS. 22 and 23. The semiconductor package 10 may be fabricated by mounting the photonic chip structure 300B that has been completed on the second package substrate 200 (of FIG. 3).

In FIGS. 10 - 18, although a method of forming the metalens 340 on the optical block 330 has been briefly described, the metalens 340 may also be directly formed on the photonic integrated circuit chip 310 through a similar process. In addition, through a process similar to that described in FIGS. 19 - 24, the photonic chip structures 300B and 300C of FIGS. 7 - 9 and the semiconductor packages 10 and 20 including the same may be manufactured.

According to an aspect of the inventive concept, there is provided a method of fabricating a photonic chip structure, the method including forming a metalens on an optical block, attaching a protective layer on the metalens, attaching an electronic integrated circuit chip on the photonic integrated circuit chip, attaching the optical block on the photonic integrated circuit chip to be horizontally spaced apart from the electronic integrated circuit chip, forming a molding layer sealing a side of an electronic integrated circuit chip, a side of the optical block, a side of the metalens, and a side of the protective layer, on the photonic integrated circuit chip, wherein the optical coupler inside the photonic chip structure, the metalens, and the protective layer are disposed to vertically overlap each other.

According to some embodiments, operation of forming the metalens on the optical block may include forming a nano-structure layer on the optical block, forming a photoresist layer on the nano-structure layer, exposing and developing the photoresist layer to form a photoresist pattern, etching the nano-structure layer along the photoresist pattern to form nano-structures, and forming a planar portion.

According to some embodiments, operation of forming the planar portion may include depositing the planar portion to fill spaces between the nano-structures, and grinding the planar portion to expose the nano-structures.

In some embodiments, the planar portion may include a material having a first refractive index, the nano-structures may include a material having a second refractive index, and a ratio of the first refractive index to the second refractive index may be greater than 1.2 and less than 5.

According to some embodiments, operation of forming the protective layer on the metalens may be performed after attaching the electronic integrated circuit chip on the photonic integrated circuit chip and attaching the optical block on the photonic integrated circuit chip, an upper surface of the metalens and an upper surface of the electronic integrated circuit chip may be disposed at a same vertical level, and the protective layer may be arranged to span the upper surface of the metalens and the upper surface of the electronic integrated circuit chip.

According to another aspect of the inventive concept, there is provided a method of fabricating a photonic chip structure, the method including forming a metalens on an inactive surface of a photonic integrated circuit chip, and attaching a protective layer on the metalens, wherein the photonic integrated circuit chip includes an optical coupler and a reflective structure having a reflective surface oriented toward the optical coupler, and the metalens, the optical coupler, and the reflective structure are vertically aligned.

According to some embodiments, operation of forming the metalens on the inactive surface of the photonic integrated circuit chip may include forming the nano-structure layer on the inactive surface of the photonic integrated circuit chip, forming a photoresist layer on the nano-structure layer, exposing and developing the photoresist layer to form a photoresist pattern, etching the nano-structure layer using the photoresist pattern to form a nano-structures, and forming a planar portion.

According to some embodiments, in operation of forming the photoresist pattern by exposing and developing the photoresist layer, the photoresist pattern may be formed in a region vertically overlapping the optical coupler, and in operation of forming the nano-structures, the nano-structures may be spaced apart from each other in at least the region vertically overlapping the optical coupler within an entire area of the planar portion.

According to some embodiments, in operation of forming the planar portion, the planar portion may be formed to cover an entire upper surface of the photonic integrated circuit chip.

According to some embodiments, operation of attaching the protective layer on the metalens may include attaching the protective layer to the upper surface of the metalens by oxide bonding or by an optical adhesive layer.

According to an embodiment, the protective layer 350 and the metalens 340 may be coupled together without an intermediate layer such as an air layer or another material layer, thereby improving the efficiency of optical signal transmission and providing the photonic chip structures 300, 300A, 300B, and 300C and the semiconductor packages 10 and 20 including the same, with improved reliability.

While the inventive concept has been described with reference to the embodiments shown in the drawings, this is merely exemplary, and it will be understood by those of ordinary skill in the art that various modifications and equivalent other embodiments can be made therefrom. Therefore, the true technical protection scope of the inventive concept should be defined by the technical spirit of the appended claims.

While the inventive concept has been particularly shown and described with reference to embodiments thereof, it will be understood that various changes in form and details may be made therein without departing from the spirit and scope of the following claims.

What is claimed is:

1. A photonic chip structure comprising:
a photonic integrated circuit chip;
a protective layer disposed over the photonic integrated circuit chip;
a metalens disposed between the photonic integrated circuit chip and the protective layer, and having an upper surface of the metalens configured to directly contact a lower surface of the protective layer; and
an optical coupler located inside the photonic integrated circuit chip and disposed to vertically overlap the metalens.

2. The photonic chip structure of claim 1, wherein the metalens comprises:
a planar portion having a first refractive index; and
a plurality of nano-structures having a second refractive index greater than the first refractive index and arranged to be spaced apart from each other within the planar portion.

3. The photonic chip structure of claim 2, wherein a ratio of the first refractive index to the second refractive index has a value greater than 1.2 and less than 5.

4. The photonic chip structure of claim 1, wherein the protective layer has a light transmittance in excess of 85% for light of a wavelength from 1200 nm to 1700 nm.

5. The photonic chip structure of claim 1, further comprising an optical block disposed between the photonic integrated circuit chip and the metalens and configured to provide a path for optical signals.

6. The photonic chip structure of claim 5, further comprising an electronic integrated circuit chip arranged on the photonic integrated circuit chip, horizontally spaced apart from the optical block, and electrically connected to the photonic integrated circuit chip,
wherein the photonic integrated circuit chip has an active surface of facing the electronic integrated circuit chip.

7. The photonic chip structure of claim 6, wherein an upper surface of the protective layer and an upper surface of the electronic integrated circuit chip are located at a same vertical level, and
the photonic chip structure further comprises a molding layer that surrounds side surfaces of each of the electronic integrated circuit chip, the optical block, the metalens, and the protective layer on the photonic integrated circuit chip.

8. The photonic chip structure of claim 6, wherein the upper surface of the metalens and an upper surface of the electronic integrated circuit chip are located at a same vertical level, and
the protective layer is disposed across the upper surface of the metalens and the upper surface of the electronic integrated circuit chip.

9. The photonic chip structure of claim 1, wherein an inactive surface of the photonic integrated circuit chip faces the metalens, and
the photonic chip structure further comprises a reflective structure positioned on a side opposite to the metalens with respect to the optical coupler and disposed inside the photonic integrated circuit chip, wherein a reflective surface of the reflective structure faces the optical coupler.

10. The photonic chip structure of claim 9, wherein the metalens is coupled directly on the photonic integrated circuit chip, and
the optical coupler is disposed inside the photonic integrated circuit chip wherein a distance between the metalens and the optical coupler is greater than 100 μm.

11. The photonic chip structure of claim 10, wherein the metalens comprises:
a planar portion disposed to cover an entire upper surface of the photonic integrated circuit chip; and
a plurality of nano-structures arranged spaced apart from each other in at least a region of an entire area of the planar portion that vertically overlaps the optical coupler, and
the protective layer is arranged to cover the entire upper surface of the metalens.

12. The photonic chip structure of claim 1, wherein the optical coupler includes at least one of a grating coupler, an edge coupler, and a transition coupler.

13. A photonic chip structure comprising:
a photonic integrated circuit chip;
an optical coupler disposed inside the photonic integrated circuit chip;
a protective layer disposed over the photonic integrated circuit chip; and
a metalens, configured to transmit optical signals transmitted through the protective layer to the optical coupler, disposed between the photonic integrated circuit chip and the protective layer and vertically aligned with the optical coupler and the protective layer.

14. The photonic chip structure of claim 13, wherein the metalens comprises:
a planar portion having a first refractive index; and
a plurality of nano-structures having a second refractive index greater than the first refractive index, arranged over the planar portion, and configured to change phases and focal points of the optical signals, and
a ratio of the first refractive index to the second refractive index is greater than 1.2 and less than 5.

15. The photonic chip structure of claim 13, further comprising an optical block disposed between the photonic integrated circuit chip and the metalens and configured to provide a path for the optical signals between the metalens and the optical coupler.

16. The photonic chip structure of claim 13, further comprising a reflective structure positioned on a side opposite to the metalens with respect to the optical coupler, disposed inside the photonic integrated circuit chip, and configured to transmit the optical signals to the optical coupler by reflecting the optical signals transmitted from the metalens.

17. A semiconductor package comprising:
a package substrate;
a semiconductor chip structure arranged over the package substrate;
a photonic chip structure arranged to be horizontally spaced apart from the semiconductor chip structure and disposed on the package substrate; and
a package molding layer surrounding the semiconductor chip structure and the photonic chip structure,
wherein the photonic chip structure comprises:
a photonic integrated circuit chip;
a protective layer disposed over the photonic integrated circuit chip;
a metalens disposed between the photonic integrated circuit chip and the protective layer, and having an upper surface of the metalens configured to directly contact a lower surface of the protective layer; and
an optical coupler disposed inside the photonic integrated circuit chip and vertically overlapping the metalens.

18. The semiconductor package of claim 17, wherein the photonic chip structure further comprises:
an optical block disposed between the photonic integrated circuit chip and the metalens and configured to be integrally formed with the metalens and to provide a path for optical signals; and
an electronic integrated circuit chip arranged to be horizontally spaced apart from the optical block on the photonic integrated circuit chip and electrically connected to the photonic integrated circuit chip,
wherein the metalens comprises:
a planar portion having a first refractive index; and
a plurality of nano-structures having a second refractive index greater than the first refractive index and arranged spaced apart from each other within the planar portion.

19. The semiconductor package of claim 17, wherein an inactive surface of the photonic integrated circuit chip faces the metalens,
wherein the photonic chip structure further comprises an electronic integrated circuit chip disposed over an active surface side of the photonic integrated circuit chip and electrically connected thereto, and
wherein the semiconductor package further comprises a reflective structure positioned on a side opposite to the metalens with respect to the optical coupler and disposed inside the photonic integrated circuit chip, wherein a reflective surface of the reflective structure faces the optical coupler.

20. The semiconductor package of claim 17, further comprising:
an interposer substrate; and
an electronic integrated circuit chip disposed within the interposer substrate and electrically connected to the photonic chip structure and the semiconductor chip structure,
wherein an inactive surface of the photonic integrated circuit chip faces the metalens,
wherein the photonic chip structure further comprises a reflective structure positioned on a side opposite to the metalens with respect to the optical coupler and disposed inside the photonic integrated circuit chip, such that a reflective surface of the reflective structure faces the optical coupler, and
wherein the metalens comprises: a planar portion arranged to cover an entire upper surface of the photonic integrated circuit chip; and a plurality of nano-structures arranged spaced apart from each other in at least a region of an entire area of the planar portion that vertically overlaps the optical coupler.
